(19) United States
(12) Patent Application Publication
(10) Pub. No.: US 2025/0149982 A1
(43) Pub. Date: May 8, 2025

(54) POWER CONVERTER WITH AUXILIARY INDUCTOR

(71) Applicant: TEXAS INSTRUMENTS INCORPORATED, Dallas, TX (US)

(72) Inventors: Robert Neidorff, Vero Beach, FL (US); Marc Davis-Marsh, San Jose, CA (US)

(21) Appl. No.: 18/501,924

(22) Filed: Nov. 3, 2023

(51) Int. Cl. H02M 3/158; H02M 3/157; H03K 17/687; H03K 19/173

(52) U.S. Cl. CPC H02M 3/158; H02M 3/157; H03K 17/687; H03K 19/173

(57) ABSTRACT

A second transistor couples to a first transistor at a switch terminal. A third transistor couples to an auxiliary inductor terminal, and the third transistor also couples to the switch terminal. A logic circuit has a switch terminal, a first, a second, and a third input and first and second outputs. The first output couples to a control input of the third transistor. The second output couples to the second transistor. A configurable delay circuit has modulation, switch terminal, and voltage inputs and first, second, and third outputs. The switch terminal input couples to the switch terminal. The first output of a configurable delay circuit couples to the first input of the logic circuit. The second output of the configurable delay circuit couples to the second input of the logic circuit. The third output of the configurable delay circuit couples to the control input of the first transistor.

### BACKGROUND

A power converter converts an input voltage into an output voltage. A switching power converter is a type of power converter that includes one or more transistors that are turned on and off in accordance with a control signal, such as a pulse width modulation control signal. A buck converter is a type of switching power converter that generates an output voltage at a lower level than the input voltage. Other types of switching power converters include boost converters and buck-boost converters.

### SUMMARY

In one example, a power converter includes a first transistor having a control input and first and second terminals. A second transistor has a control input and first and second terminals. The first terminal of the second transistor is coupled to the second terminal of the first transistor at a switch terminal. A third transistor has a control input and first and second terminals. The first terminal of the third transistor is coupled to an auxiliary inductor terminal, and the second terminal of the third transistor coupled to the switch terminal. A logic circuit has a switch terminal input, a first input, a second input, a third input, first output, and a second output. The first output is coupled to control input of the third transistor, and the second output coupled to the control input of the second transistor. A configurable delay circuit has a modulation input, a switch terminal input, a voltage input, a first output, a second output, and a third output. The switch terminal input of the configurable delay circuit is coupled to switch terminal. The first output of the configurable delay circuit is coupled to the first input of the logic circuit. The second output of the configurable delay circuit is coupled to the second input of the logic circuit, and the third output of the configurable delay circuit coupled to the control input of the first transistor.

### BRIEF DESCRIPTION OF THE DRAWINGS

FIG. 1 is a block diagram of an example power converter having an auxiliary inductor to partially charge the switch terminal.

FIG. 2 is a timing diagram illustrating the operation of the power converter, in an example.

FIG. 3 is a graph identifying a suitable point for charging the switch terminal, in an example.

FIG. 4 is a flowchart of a method for partially charging the switch terminal, in an example.

FIG. 5 is a block diagram of a processing circuit for partially charging the switch terminal, in an example.

### DETAILED DESCRIPTION

The same reference numbers or other reference designators are used in the drawings to designate the same or similar (either by function and/or structure) features.

A synchronous buck converter is a type of switching power converter in which two transistors are coupled in series between an input voltage terminal and a ground terminal. The connection between the transistors is referred as the switch (SW) terminal, which is also coupled to an inductor. The transistor coupled to the input voltage terminal may be referred to as the “high side” (HS) transistor, and the transistor coupled to the ground terminal may be referred to as the “low side” (LS) transistor. In accordance with a pulse width modulation (PWM) control signal, a control circuit turns on one of the transistors and then, after a “dead-time,” turns on the other transistor. When the LS transistor is on, the voltage on the SW terminal is approximately 0V. For example, due to current flowing through the on-resistance of the LS terminal, the SW terminal voltage may be a slightly negative voltage.

Upon turning off the LS transistor, the control circuit waits for a dead time before turning on the HS transistor. During the dead-time, current may continue to flow from ground through the body diode of the LS transistor to the SW terminal. The voltage drop across the body diode (e.g., 0.7V) forces the SW terminal voltage to an even larger negative voltage. When the control circuit then begins to turn on the HS transistor, a voltage equal to the input voltage (Vin) plus the body diode voltage drop is present across the terminals (e.g., drain and source) of the HS transistor. Current begins to flow through the channel of the HS transistor with a relatively large voltage drop across the transistor. The current that begins to flow through the HS transistor as the HS transistor begins to turn on also charges the parasitic capacitance present on the SW terminal (e.g., the drain-to-source capacitance of the LS transistor). Accordingly, significant power dissipation may occur each time the HS transistor is turned on-power dissipation that is referred to as “switching loss.”

Switching losses are, to at least some extent, proportional to the square of the input voltage. Accordingly, switching losses can be particularly problematic at higher levels of input voltage, particularly, for some applications. For example, an automobile may have a 12V battery and, accordingly, the input voltage to the power converters in the automobile is 12V. Increasingly, automobiles are being equipped with more and more electronics. The increase in electrical load in automobiles means that, for the same 12V battery, the cabling carries increasing levels of current. Increases in the current carried by the automobile's cables result in an increase in the cross-sectional area of the cables, which makes the cables heavier and more difficult to route around tight corners within the chassis of the automobile. One approach to addressing the automobile cabling issue is to provide a higher voltage battery. For example, an automobile having a 48V battery can have thinner and lighter weight cables than an automobile with a 12V battery. However, power converters with a 48V input voltage will have significantly higher switching losses than power converters with a 12V input voltage.

One approach to reduce the switching loss of the HS transistor includes the use of an auxiliary inductor. When the LS transistor is on, current flows through the LS transistor to the main inductor of the buck converter and during this time, current can also be allowed to flow to the auxiliary inductor. Energy is thereby stored in the auxiliary inductor. During the ensuing dead-time, when the LS transistor is turned off, the auxiliary inductor discharges its energy into the SW terminal resulting in an increase in the voltage on the SW terminal until the SW terminal reaches the level of the input voltage Vin. Then, when the control circuit turns on the HS transistor, current begins to flow through the HS transistor with little if any voltage drop across the drain and source terminals of the transistor thereby greatly reducing or eliminating the switching loss associated with the HS transistor.

The use of the auxiliary inductor as described above to charge the SW terminal before turning on the HS transistor, however, results in losses associated with the auxiliary inductor. The resistance of the auxiliary inductance causes a conduction loss in the auxiliary inductor. In accordance with the example described below, the control circuit uses the auxiliary inductor to partially charge the SW terminal before turning on the HS transistor. In one example, the control circuit causes the SW terminal to be charged to approximately one-half the input voltage (Vin/2). Then, as the control circuit begins to turn on the HS transistor, the voltage drop across the HS transistor is approximately Vin/2, which is significantly less than what would have been the case absent the auxiliary inductor. Using the auxiliary inductor to charge the SW terminal to a fraction of Vin, Vin/K (e.g., K=2), and then using the HS transistor to finish charging the SW terminal to Vin results in a more efficient buck converter than not using an auxiliary inductor at all or using an auxiliary inductor to charge the SW terminal to the full Vin.

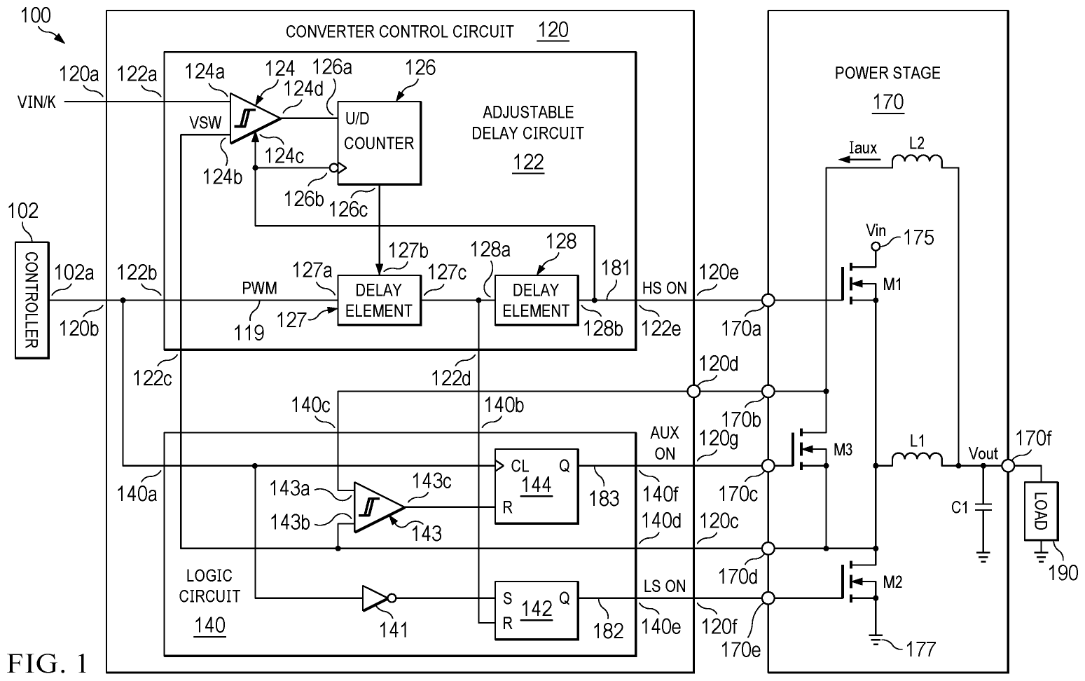

FIG. 1 is a block diagram of a power converter 100, in an example. Power converter 100 converts an input voltage Vin to an output voltage Vout to drive a load 190. Power converter 100 in the example of FIG. 1 is a synchronous buck converter but the principles described herein are applicable to other types of power converters including, for example, asynchronous buck converters and boost converters as well as class D audio amplifiers. Power converter 100 includes a controller 102, a converter control circuit 120, and a power stage 170. Controller 102 includes a controller output 102a. Controller 102 generates a PWM signal 119, described below. Controller 102 may include an analog circuit, a digital circuit, or a combination of analog and digital circuit components. In some examples, controller 102 may include a processor that executes machine instructions. Power stage 170 has power stage terminals 170a, 170b, 170c, 170d, 170c, and 170f.

Converter control circuit 120 includes a voltage input 120a, a modulation input 120b, a switch terminal input 120c, an input terminal 120d, and outputs 120e, 120f, and 120g. Voltage input 120a receives the input voltage, Vin, scaled by a scaling factor K. In one example, scaling factor K is 2, and accordingly, the voltage input 122a receives Vin/2. In another example, scaling factor K is a value between 1.8 and 2.2. Modulation input 120b is coupled to controller output 102a. Switch terminal input 120c is coupled to terminal 170d of power stage 170. Input terminal 120d is coupled to terminal 170b. Outputs 120e, 120f, and 120g of converter control circuit 120 are coupled to terminals 170a, 170e, and 170c, respectively, of power stage 170. Terminal 170f is the output terminal of power converter 100 and can be coupled to load 190.

In the example of FIG. 1, converter control circuit 120 includes a configurable delay circuit 122 coupled to a logic circuit 140. Configurable delay circuit 122 has a voltage input 122a, a modulation input 122b, a switch terminal input 122c, and outputs 122d and 122e. Voltage input 122a and modulation input 122b of configurable delay circuit 122 are coupled to voltage input 120a and modulation input 120b, respectively, of converter control circuit 120. Switch terminal input 122c of configurable delay circuit 122 is coupled to switch terminal input 120c of converter control circuit 120. Output 122e of configurable delay circuit 122 is coupled to output 120e of converter control circuit 120.

Logic circuit 140 has inputs 140a, 140b, and 140c, a switch terminal input 140d, and outputs 140c and 140f. Input 140a of logic circuit 140 is coupled to modulation input 120b of converter control circuit 120. Input 140b of logic circuit 140 is coupled to output 122d of configurable delay circuit 122. Input 140c of logic circuit 140 is coupled to terminal 120d of converter control circuit 120. Switch terminal input 140d is coupled to switch terminal input 122c. Outputs 140e and 140f are coupled to outputs 120f and 120g, respectively.

Configurable delay circuit 122 includes a comparator 124, a counter 126, and delay elements 127 and 128. Comparator 124 may be a latched comparator having comparator inputs 124a and 124b, a latch input 124c, and a comparator output 124d. Counter 126 has a control input 126a, a clock input 126b, and a counter output 126c. Delay element 127 has an input 127a, a delay control input 127b, and a delay output 126c. Delay element 128 has an input 128a and a delay output 128b. Comparator inputs 124a and 124b are coupled to voltage input 122a and modulation input 122b, respectively. Latch input 124c and clock input 126b are coupled to delay output 128b. Delay output 128b is coupled to output 122e of configurable delay circuit 122.

Comparator output 124d is coupled to control input 126a. The control input 126a may be an up/down control input. In one example, a logic high at control input 126a causes the counter to increment its count value, and a logic low causes the counter to decrement its count value. Comparator output 126c is coupled to delay control input 127b. Modulation input 122b is coupled to input 127a of delay clement 127 and to output 122d is coupled to the modulation input 122b. Delay output 127c is coupled to input 128a of delay element 128 and to output 122d of configurable delay circuit 122.

In the example of FIG. 1, logic circuit 140 includes an inverter 141, a set-reset (SR) flip-flop 142, a comparator 143, and a latch 144. Latch 144 may be an edge-triggered latch. A data (D) flip-flop may be used instead of latch 144 in other examples. Input 140a of logic circuit 140 is coupled to an input of inverter 141 and to a clock input of latch 144. SR flip-flop has a set(S) input, a reset (R) input, and an output (Q). The output of inverter 141 is coupled to the S input of SR flip-flop 142. Input 140b of logic circuit 140 is coupled to the R input of SR flip-flop 142, The SR flip-flop's Q output is coupled to output 140e of logic circuit 140. The signal from the Q output of SR flip-flop 142 is LS ON 182 and causes transistor M2 to turn on when LS ON 182 is logic high (e.g., by forcing the gate-to-source voltage (Vgs) of transistor M2 to exceeds its threshold voltage) and off when LS ON 182 is logic low (Vgs below the threshold voltage). Comparator 143 has comparator inputs 143a and 143b and a comparator output 143c. Input terminal 120d is coupled to comparator input 143a. Power stage terminal 170d is coupled to comparator input 143b. In addition to the clock input, latch 144 has an R input and a Q output. The comparator output 143c is coupled to the R input of latch 144. The Q output of latch 144 is coupled to output 140f of logic circuit 140. The signal from the Q output of latch 144 is AUX ON 183 and causes transistor M3 to turn on when AUX ON 183 is logic high (e.g., by forcing the gate-to-source voltage (Vgs) of transistor M3 to exceeds its threshold voltage) and off when AUX ON 183 is logic low (Vgs below its threshold voltage).

Power stage 170 includes transistors M1, M2, and M3, inductors L1 and L2, and a capacitor C1. Transistors M1-M3 are n-channel field effect transistors (NFETs) in the example of FIG. 1 but can be implemented as other types of transistors in other examples. The drain of transistor M1 is coupled to an input voltage terminal 175 (Vin) and the source of transistor M2 is coupled to a ground terminal 177. The source of transistor M1 is coupled to the drain of transistor M2 at power stage terminal 170d, which is also referred to as the switch (SW) terminal 170d. The voltage at the SW terminal 170d is referred to herein as Vsw. Inductor L1 is coupled between the SW terminal 170d and capacitor C1. Capacitor C1 is coupled between the output terminal 170f and ground. The gates of transistors M1 and M2 are coupled to terminals 170a and 170e, respectively. The signal from the delay output 128b of delay element 128 is HS ON 181 and causes transistor M1 to turn on when HS ON 181 is logic high (e.g., by forcing the gate-to-source voltage (Vgs) of transistor M1 to exceeds its threshold voltage) and off when HS ON 181 is logic low (Vgs less than its threshold voltage). Transistor M3 and inductor L2 are coupled in series between the power stage output terminal 170f and the SW terminal 170d. The gate of transistor M3 is coupled to power stage terminal 170c. In one example, when transistor M3 is “off”, no current flows in either direction through transistor M3. In an example, a diode can be coupled in series with transistor M3. In another example, transistor M3 may include two transistors coupled in series. In yet another example, the transistor's body connection may be available and used to block current flow through the parasitic body diode. In some examples, inductor L1 may be referred to as the “main” inductor for the power converter, and inductor L2 may be referred to as the “auxiliary” inductor.

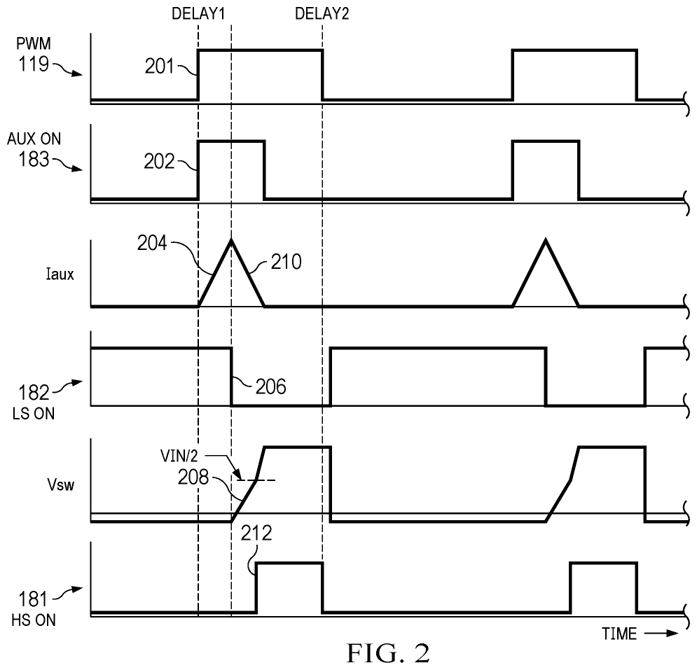

FIG. 2 is a timing diagram illustrating the operation of power converter 100. FIG. 2 includes example waveforms for the PWM signal 119, LS ON signal 182, the HS ON signal 181, the AUX ON signal 183, switch terminal voltage Vsw, and current Iaux through auxiliary inductor L2. Referring to FIGS. 1 and 2, controller 102 initiates a PWM cycle by forcing PWM signal 119 to a logic high state as indicated by rising edge 201. The rising edge 201 of PWM signal 119 is received by the clock input of latch 144 which causes a rising edge 202 of the AUX ON signal from the Q output of latch 144. AUX ON being logic high causes transistor M3 to turn on.

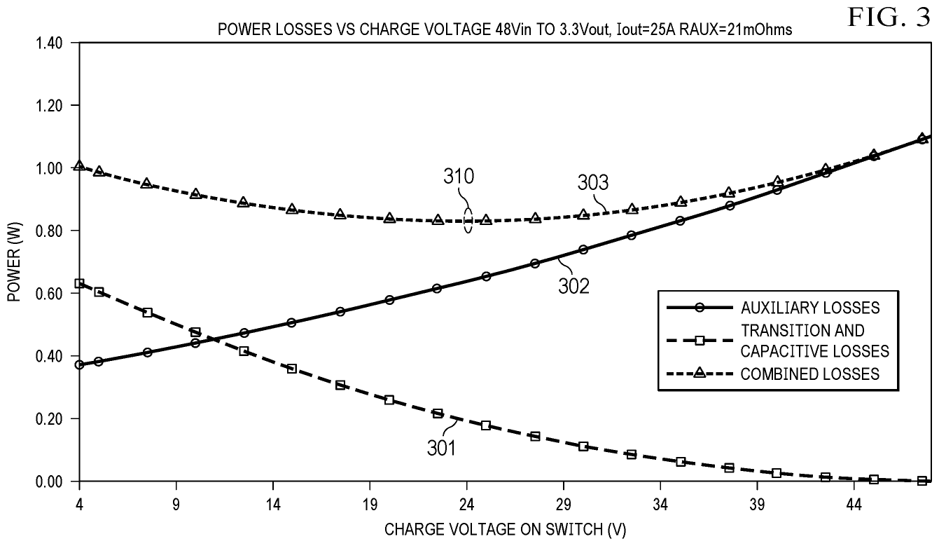

With transistor M3 on, current flows through from ground, and through transistors M2 and M3 to inductor L2. The direction of current Iaux is designated in FIG. 3 from the drain of transistor M3 to the source of transistor M3. Accordingly, current Iaux increases as indicated at 204 in FIG. 2 and energy is stored in auxiliary inductor L2.

Delay element 127 also receives the rising edge 201 of PWM signal 119. Delay element 127 introduces a delay (DELAY1 in FIG. 2) in response to the rising edge 201. In one example, delay element 127 introduces an adjustable delay in response to a rising edge at its input 127a but does not introduce the configurable delay in response to a falling edge at its input 127a. As described below, the length of the configurable delay is programmed into delay element by counter 126. The delayed output signal from delay element 127 is provided to the R input of SR flip-flop 142. A rising edge on the R input of SR flip-flop 142 causes the LS ON signal 182 at its Q output to be forced low as indicated by falling edge 206. Accordingly, transistor M2 is turned off after the DELAY1 time period implemented by delay element 127.

Upon transistor M2 turning off, auxiliary inductor L2 begins to discharge at least some of its energy to thereby charge the capacitance on the SW terminal 170d. Current Iaux continues to flow from auxiliary inductor L2 through transistor M3 into the SW terminal 170d but decreases as indicated by reference numeral 210. In response, the voltage Vsw increases as indicated by reference numeral 208. Current Iaux continues to decrease after the rising edge of 212 of the HS_ON signal. Current Iaux stops flowing as a result of transistor M3 turning off.

The delayed signal from delay element 127 is also provided to delay element 128, which introduces an additional delay (DELAY2). In some examples, the delay introduced by delay element 128 is a fixed delay (non-configurable). In some examples, delay element 128 introduces a fixed delay in response to a rising edge at its input 128a but does not introduce the fixed delay in response to a falling edge at its input 128a. The rising edge 212 of the HS ON signal to the gate of transistor M1 is a delayed version of rising edge 201 of the PWM signal. The length of the delay of rising edge 212 relative to rising edge 201 is the sum of DELAY1 and DELAY2. Accordingly, transistor M1 is turned on following a delay of DELAY1 plus DELAY2 from rising edge 201 of the PWM signal. Transistor M1 is turned on after energy is stored in auxiliary inductor L2 and after transistor M2 is turned off.

Configurable delay circuit 122 configures the delay DELAY1 into delay element 127 such that the SW terminal 170d is charged to a voltage of approximately Vin/2 when transistor M1 is turned on. In one example, configurable delay circuit 122 configures the delay DELAY1 such that the SW terminal 170d is charged to a voltage that is within 10% of being one-half the voltage of the input voltage Vin. The rising edge 212 of HS ON is received by the latch input 124c of comparator 124 and the clock input 126b of counter 126. Comparator 124 compares Vin/K (e.g., K=2) to Vsw each time transistor M1 is turned on to determine whether Vsw was indeed approximately equal to Vin/2. If voltage Vin/2 is larger than Vsw, then Vsw had not yet reached Vin/2 when transistor M1 turned on. In this case, comparator 124 outputs a logic high signal to the control input 126a of counter 126. In response to a logic high at input 126a, counter 126 increments its count value. The incremented count value is provided to the delay control input 127b of delay element 127, which then increases the length of DELAY1.

However, if voltage Vin/2 is smaller than Vsw, then Vsw was larger than Vin/2 when transistor M1 turned on. In that case, comparator 124 outputs a logic low signal to the control input 126a of counter 126. In response to a logic low at input 126a, counter 126 decrements its count value. The decremented count value is provided to the delay control input 127b of delay element 127, which then decreases the length of DELAY1. The configurable delay circuit 122 adjusts the length of DELAY1 to ensure that transistor M1 is turned on when Vsw is approximately equal to Vin/2.

As described above, some power converters do not include an auxiliary inductor L2. Accordingly, when the HS transistor (e.g., transistor M1 in the example of FIG. 1) turns on, the Vds of the HS transistor is Vin and the HS transistor has relatively high switching losses. Other power converters include an auxiliary inductor that charges the switch terminal to Vin to minimize the switching loss in the HS transistor but result in conduction losses in the auxiliary inductor. In the example of FIG. 1, power converter 100 charges the SW terminal 170d to approximately Vin/2 when transistor M1 turns on. As explained below with respect to FIG. 3, the combination of the switching losses of transistor M1 and the conduction loss of auxiliary inductor L2 is lower than the losses of either of two power conductors described above—(a) a power converter that has no auxiliary inductor and the SW terminal is not charged at all when the HS transistor is turned on and (b) a power converter in which an auxiliary inductor charges the SW terminal to Vin before the HS transistor is turned on.

FIG. 3 is a graph containing plots 301, 302, and 303. Power loss is on the y-axis and switch terminal voltage is on the x-axis. The data in this example is for a power converter in which the input voltage Vin is 48V. Plot 301 is an example plot illustrating the losses due to transition and capacitive losses associated with transistor M1 turning on. The transition losses represent the power dissipated by current flowing through the channel of transistor M1 while the Vds of transistor M1 is greater than 0V. The capacitive losses occur when transistor M1 is turned on and discharges its parasitic capacitance which was charged to a voltage of Vin-Vsw. The transition and capacitive losses associated with transistor M1 decrease as the voltage on the SW terminal 170d increases. Plot 302 is an example plot illustrating the losses due to the auxiliary inductor L2. Such losses are proportional to the integral of the product of the inductor current and the on-resistance of transistor M3. The losses due to the use of the auxiliary inductor L2 increases as the voltage on the SW terminal 170d increases. Plot 303 is the sum of plots 301 and 302 and thus represents the transition and capacitive losses plus the losses due to the use of the auxiliary inductor current. Plot 303 thus represents the combined losses. Point 310 identifies the lowest point for plot 310 which occurs at approximately 24V which is approximately one-half of the input voltage of 48V in this example.

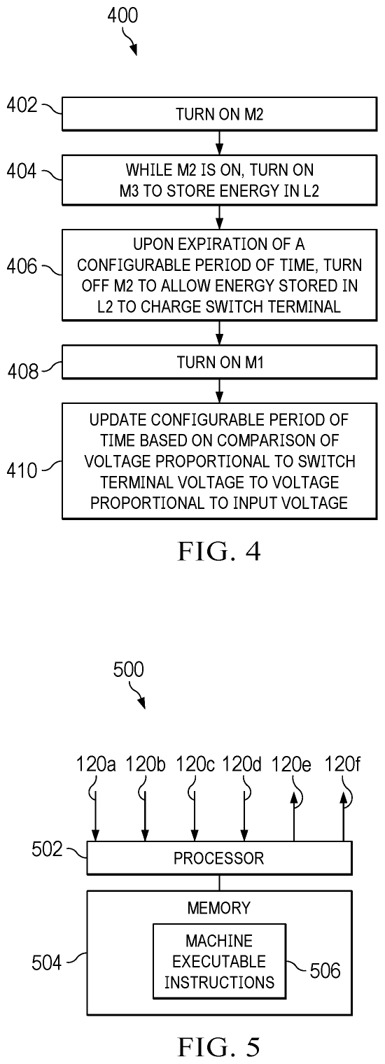

FIG. 4 is a flow chart 400 illustrating a method implemented by power converter 100. In block 402, the method includes turning on transistor M2. At block 404, while transistor M2 is on, the method includes turning on transistor M3 to cause current to flow to and energy to be stored in the auxiliary inductor L2. At block 406, following a configurable period of time (e.g., DELAY1), transistor M2 is turned off. By turning off transistor M2, energy stored in auxiliary inductor L2 is used to charge the SW terminal 170d. At block 408, transistor M1 is then turned on. At block 410 the method includes updating the configurable period of time based on a comparison of a voltage proportional to the switch terminal voltage to a voltage proportional to the input voltage. In one example, the voltages proportional to the switch terminal voltage and the input voltage are Vsw and Vin/K, respectively, in which e.g., K=2. In another example, the voltages proportional to the switch terminal voltage and the input voltage are Vsw*K and Vin, respectively.

FIG. 5 is a block diagram in which converter control circuit 120 includes a processing circuit 500. Processing circuit 500 can perform the functionality described herein attributed to the converter control circuit 120 and its constituent circuits (FIG. 1). Processing circuit 500 includes one or more processors 502 coupled to a non-transitory storage medium 504. The non-transitory storage medium 504 may include volatile memory (e.g., random access memory), non-volatile memory (e.g., read only memory, flash memory, etc.), or a combination thereof. Non-traditional storage medium 504 stores machine executable instructions (e.g., firmware) that can be executed by processor(s) 502 to perform the functionality described herein attributed to the converter control circuit 120.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “ON” or “enabled” means that the conduction channel of the FET is present and drain current may flow through the FET. References herein to a FET being “OFF” or “disabled” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

What is claimed is:

1. A power converter, comprising:
a first transistor having a control input and first and second terminals;
a second transistor having a control input and first and second terminals, the first terminal of the second transistor coupled to the second terminal of the first transistor at a switch terminal;
a third transistor having a control input and first and second terminals, the first terminal of the third transistor coupled to an auxiliary inductor terminal, and the second terminal of the third transistor coupled to the switch terminal;
a logic circuit having a switch terminal input, a first input, a second input, a third input, first output, and a second output, the first output coupled to control input of the third transistor, and the second output coupled to the control input of the second transistor; and
a configurable delay circuit having a modulation input, a switch terminal input, a voltage input, a first output, a second output, and a third output, the switch terminal input of the configurable delay circuit coupled to switch terminal, the first output of the configurable delay circuit coupled to the first input of the logic circuit, the second output of the configurable delay circuit coupled to the second input of the logic circuit, and the third output of the configurable delay circuit coupled to the control input of the first transistor.

2. The power converter of claim 1, wherein the configurable delay circuit comprises:
a counter having a control input and a counter output; and
a delay element having a signal input, a delay control input, and a delay output, the signal input coupled to the modulation input, the delay control input coupled to the counter output, and the delay output coupled to the second output of the configurable delay circuit.

3. The power converter of claim 2, further comprising a comparator having first and second comparator inputs, and a comparator output, the first comparator input coupled to the voltage input, the second comparator input coupled to the switch terminal input of the configurable delay circuit, and the comparator output coupled to the control input of the counter.

4. The power converter of claim 3, wherein the delay element is a first delay element and the comparator includes a latch input, and the configurable delay circuit includes a second delay element having an input and a delay output, the input of the second delay element coupled to the delay output of the first delay element, and the delay output of the second delay element coupled to the third output of the configurable delay circuit and to the latch input.

5. The power converter of claim 4, wherein, in response to a signal assertion at the latch input, the counter is configured to:
increase a count value at the counter output responsive to a signal at the control input of the counter being at a first logic state; and
decrease the count value at the counter output responsive to the signal at the control input of the counter being at a second logic state.

6. The power converter of claim 1, wherein the logic circuit comprises:
a latch having a clock input and a latch output, the clock input coupled to the first input of the logic circuit and the latch output coupled to the first output of the logic circuit;
an inverter having an input and an output, the input coupled to the first input of the logic circuit; and
a set-reset (SR) flip-flop having a set(S) input, a reset (R) input, and an output, the S input coupled to the output of the inverter, the R input coupled to the second input of the logic circuit, and the output of the SR flip-flop coupled to the control input of the second transistor.

7. The power converter of claim 6, wherein the latch has an R input, and the logic circuit further comprises a comparator having first and second comparator inputs and a comparator output, the first comparator input coupled to the third input of the logic circuit, the second comparator input coupled to the switch terminal input of the logic circuit, and the comparator output coupled to the R input of the latch.

8. The power converter of claim 7, wherein the configurable delay circuit includes:
a first delay element having a delay input and a delay output, the delay input of the first delay element coupled to the first output of the configurable delay circuit, and the delay output of the first delay element coupled to the second output of the configurable delay circuit; and
a second delay element having a delay input and a delay output, the delay input of the second delay element coupled to the second output of the configurable delay circuit, and the delay output of the second delay element coupled to the third output of the configurable delay circuit.

9. The power converter of claim 8, wherein a time delay of the first delay element is adjustable.

10. A power converter, comprising:
a first transistor having a control input and first and second terminals;
a second transistor having a control input and first and second terminals, the first terminal of the second transistor coupled to the second terminal of the first transistor at a switch terminal;
a third transistor having a control input and first and second terminals, the first terminal of the third transistor coupled to an auxiliary inductor terminal, and the second terminal of the third transistor coupled to the switch terminal; and
a converter control circuit having a voltage input, a switch terminal input, and first, second, and third outputs, the switch terminal input coupled to the switch terminal, the first output coupled to the control input of the first transistor, the second output coupled to control input of the second transistor, and the third output coupled to control input of the third transistor, wherein the converter control circuit is configured to:
turn on the second transistor;
while the second transistor is on, turn on the third transistor for a configurable delay period;
upon expiration of the configurable delay period, turn off the second transistor; and
after the second transistor is off, turn on the first transistor and update the configurable delay period based on a comparison of a voltage proportional to a voltage at the switch terminal input to a voltage proportional to a voltage at the voltage input.

11. The power converter of claim 10, wherein the converter control circuit is configured to:
increase the configurable delay period based on the voltage proportional to the voltage at the switch terminal being smaller than the voltage proportional to the voltage at the voltage input; and
decrease the configurable delay period based on the voltage proportional to the voltage at the switch terminal being larger than the voltage proportional to the voltage at the voltage input.

12. The power converter of claim 10, wherein the converter control circuit has a modulation input and the converter control circuit comprises an adjustable delay element between the modulation input and the first output.

13. The power converter of claim 12, wherein the adjustable delay element has an input and a delay output, wherein the converter control circuit comprises:
a second delay element having a delay input and a delay output, the delay input of the second delay element coupled to the delay output of the adjustable delay element, and the delay output of the second delay element coupled to the first output;
a comparator having first and second comparator inputs and a comparator output, the first comparator input coupled to the voltage input, and the second comparator input coupled to the switch terminal input; and
a counter having a control input, a clock input, and a counter output, the control input coupled to the comparator output, the clock input coupled to the delay output of the second delay element, and the counter output coupled to the adjustable delay element.

14. The power converter of claim 13, wherein the comparator is a latched comparator and includes a latch input coupled to the delay output of the second delay element.

15. The power converter of claim 10, wherein the converter control circuit has a modulation input, and the converter control circuit comprises:
a latch having a clock input and an output, the clock input coupled to the modulation input, and the output of the latch coupled to the control terminal of the third transistor;
an inverter having an inverter input and an inverter output, the inverter input coupled to the modulation input; and
a set-reset (SR) flip-flop having a set(S) input, a reset (R) input, and an output, the S input coupled to the inverter output, the R input coupled to the delay output of the adjustable delay element, and the output of the SR flip-flop coupled to the control input of the second transistor.

16. The power converter of claim 10, wherein the converter control circuit comprises a processor configured to:
cause the second transistor to turn on;
while the second transistor is on, cause the third transistor to turn on for a configurable delay period;
upon expiration of the configurable delay period, cause the second transistor to turn off; and;
after the second transistor is off, cause the first transistor turn on and update the configurable delay period.

17. A system, comprising:
a load; and
a switching power converter including:
a first transistor having a control input and first and second terminals, the first terminal coupled to an input voltage terminal;
a second transistor having a control input and first and second terminals, the first terminal of the second transistor coupled to the second terminal of the first transistor at a switch terminal;
a third transistor having a control input and first and second terminals, the first terminal of the third transistor coupled to an auxiliary inductor terminal, and the second terminal of the third transistor coupled to the switch terminal;
a first inductor coupled between the switch terminal and the load;
a second inductor coupled between the load and the first terminal of the third transistor;
a controller having a controller output; and
a converter control circuit having a voltage input, a switch terminal input, a modulation input, and first, second, and third outputs, the switch terminal input coupled to the switch terminal, the modulation input coupled to the controller output, the first output coupled to the control input of the first transistor, the second output coupled to control input of the second transistor, and the third output coupled to control input of the third transistor, wherein the converter control circuit is configured to:
turn on the second transistor;
while the second transistor is on, turn on the third transistor for a period of time to store energy in the second inductor;
upon expiration of the period of time, cause a voltage at the switch terminal to increase to a voltage that is within 10% of being one-half the voltage of the input voltage terminal by turning off the second transistor for a period of time; and
after the second transistor is off, turn on the first transistor.

18. The system of claim 17, wherein the converter control circuit is configured to adjust the period of time.

19. The system of claim 17, wherein the converter control circuit is configured to adjust the period of time by comparing a voltage proportional to the voltage at the switch terminal to a voltage proportional to a voltage at the input voltage terminal.

20. The system of claim 19, wherein the converter control circuit includes:
a comparator having first and second inputs and a comparator output, the first input of the comparator coupled to the voltage input, the second input of the comparator coupled to the switch terminal input;
a counter having a control input and a counter output, the control input coupled to the comparator output; and
an adjustable delay element having an input and a delay output, the input of the adjustable delay element coupled to the modulation input; and
a second delay element having an input and a delay output, the input of the second delay element coupled to the delay output of the adjustable delay element, and the delay output of the second delay element coupled to the first output.
